(19) United States
(12) Patent Application Publication
(10) Pub. No.: US 2006/0012035 A1
(43) Pub. Date: Jan. 19, 2006

(54) Method of packaging integrated circuits, and integrated circuit packages produced by the method

(75) Inventors: Elstan Anthony Fernandez, Aljunied Crescent (SG); Kok Cheong Bernard Yeong, Hougang (SG)

Correspondence Address: Harold C Moore;Maginot Moore & Beck, 111 Monument Circle, Suite 3000, Indianapolis, IN, 46204, US

(73) Assignee: INFINEON TECHNOLOGIES AG, 81669 Munchen (DE)

(21) Appl. No.: 10/538,275

(22) PCT Filed: Dec. 10, 2002
(86) PCT No.: PCT/SG02/00288

§ 371 Date: Jun. 10, 2005

(51) Int. Cl. H01L 23/48; H01L 21/58

(52) U.S. Cl. 257/723; 257/738; 257/778; 438/126; 438/108; 438/109

(57) ABSTRACT

A method of packaging integrated circuits is proposed in which two integrated circuits 13, 17 are provided in register on opposite sides of a single substrate 1. Electrical contacts on the each of the integrated circuits 13, 17 are electrically connected to electrical conductors of the substrate 1. One of the integrated circuits 17 may be wire bonded to the substrate, while the other is a flip-chip 13. Holes 7 are provided through the substrate 1 so that in a moulding operation a single resin body 21 may be formed encasing both of the integrated circuits 13, 17 by applying resin only to an upper side of the substrate 1 and allowing the resin to flow to the other side of the substrate 1 into a volume defined by a box 15.

### FIELD OF THE INVENTION

The present invention relates to methods of packaging integrated circuits, and integrated circuits produced using the method.

### BACKGROUND OF INVENTION

It is well known to provide integrated circuits packages in which integrated circuits (dies) are located within resin bodies. Electrical contacts of the each integrated circuit are electrically in contact with corresponding electrical conductors which protrude out of the resin body.

In one type of package, the integrated circuits are located on a die pad portion of a lead frame with the electric contacts facing away from the lead frame, and wires are formed between the electric contacts and respective lead fingers of the lead frame. The resin is applied to encase the integrated circuits and the wires in the resin body, leaving a portion of the lead frames protruding from the resin body. The lead fingers are then cut to separate them from the remainder of the lead frame, and thus singulate the packages. An alternative type of integrated circuit is called a “flip chip” which is positioned on (and normally adhered to) a substrate (a term which will be used very generally here, for example to include also a lead frame) with the electrical contacts facing the substrate, and in electrical contact with corresponding electric contacts provided in the substrate. The electric contacts on the substrate are typically electrically connected to electrically conductive paths formed through the material of the substrate. The flip-chip is typically encased in a resin body which secures it to the substrate to form a package.

There is pressure to improve integrated circuits packages to increase the number of input/output connections (I/Os), reduce the package footprint, reduce the package thickness and improve the thermal management (that is, reduce the risk of the integrated circuit overheating).

Various proposals have been made to do this, typically proposing that a plurality of dies are packaged into a single package. For example, it is known to provide a plurality of dies inside a single package stacked one above the other with an adhesive paste between them. It is further known to provide two dies placed side by side (e.g. on a lead frame) within a single resin body.

One disadvantage with providing a stacked die package assembly is that the thickness of the package is increased. Additionally, there are reliability concerns due to the presence of the adhesive layer between the dies, and due to the reduced possibilities for heat dissipation which in turn lead to an increased risk of overheating.

Conversely, providing the dies side by side means that the footprint of the package is increased.

### SUMMARY OF THE INVENTION

The present invention aims to provide new and useful methods for packaging integrated circuits, and integrated circuit packages produced using the methods.

In general terms, the present invention proposes that two integrated circuits are provided in register on opposite sides of a single substrate and that electrical contacts on the both of the dies are electrically connected to electrical contacts of the substrate.

Conventional moulding techniques are not well adapted for applying resin simultaneously to both sides of a substrate, so that if the invention is implemented using conventional techniques two successive moulding operations would be required, each forming a resin body on a respective side of the sides of the substrate. This would significantly complicate the complexity of the moulding. For that reason, the substrate is preferably provided with holes through which resin can flow during a moulding operation, so that both of the integrated circuits can be encased in a single resin body during a single moulding operation in which resin is applied to only one side of the substrate (e.g. the upper side).

During the moulding operation a moulding element should be provided to define a cup enclosing the lower integrated circuit, and thereby define the shape of the portion of the resin body on the lower surface of the substrate.

This moulding element may be formed as a portion of a mould in which the substrate and integrated circuits are located during the moulding operation. However, more preferably, the moulding element may be a box element which is permanently connected to the substrate (e.g. by the moulding operation itself) and which remains in the completed package.

Preferably, at least one of the integrated circuits is provided as a flip chip. For example, one of the integrated circuits may be a flip-chip and the other an integrated circuit requiring wire bonding.

One of the integrated circuits may be provided on the same side of the substrate as eutectic solder balls which provide electrical contacts out of the substrate. In this case, the eutectic solder balls may be arranged on a surface of the substrate in an array including at least one opening, and the integrated circuit may be provided in the openings.

This is particularly suitable in the case that the integrated circuit which is provided on the same side of the substrate as the eutectic solder balls is a flip-chip. Since a flip-chip does not include wire bonds, it can be packaged with a thinner resin body than an integrated circuit which includes wire bonds. Preferably the portion of the resin body on this side of the substrate, and the box if one is provided,. extend from the substrate by a distance which is less than the maximum distance to which the eutectic balls extend from the substrate. To make this easier to achieve the integrated circuit on this side of the substrate may be provided in a recess in the substrate. Preferably the recess exposes electrical elements in the substrate to which the integrated circuit is connected.

The resin moulding process may optionally be performed in a vacuum, to avoid the risk of pockets of ambient atmosphere gases (air) being trapped in the resin body. Alternatively, this can be achieved by a proper design of the moulding arrangement. For example, in the case that resin is applied from the upper side of the substrate and is intended to flow through the holes to the lower side of the substrate, the box (or other moulding element) at the lower side of the substrate may include openings to allow the air to escape.

### BRIEF DESCRIPTION OF THE FIGURES

Preferred features of the invention will now be described, for the sake of illustration only, with reference to the following figures in which:

FIG. 1 is a view of a first surface of a substrate for use in a method which is an embodiment of the invention;

FIG. 2 is a cross-sectional view illustrating a moment during the implementation of the packaging method of FIG. 1;

FIG. 3 is a cross sectional view of package produced by the method of FIG. 1;

FIG. 4 is an exploded view of the package of FIG. 3.

### DETAILED DESCRIPTION OF THE EMBODIMENTS

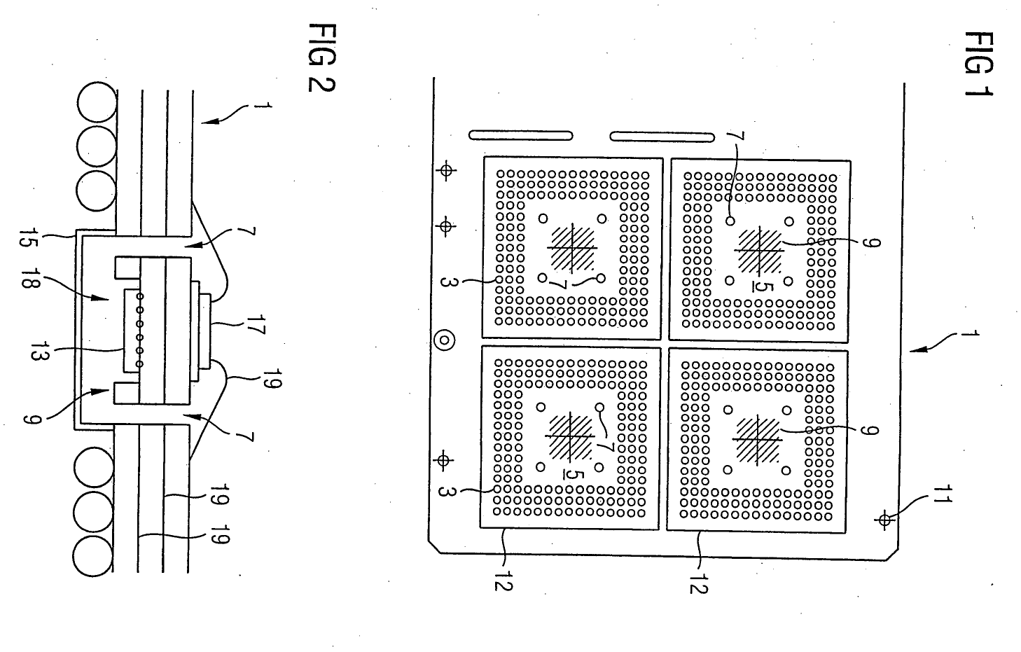

Referring firstly to FIG. 1, a substrate 1 for use in a method which is an embodiment of the invention is a planar member which includes a first surface on which a plurality of solder balls 3 are arranged in a rectangular array. The array includes regions 5 in which there are no solder balls 3. In each of these regions 5 are four holes 7 which extend though the substrate 1 perpendicular to the plane of the substrate. The regions 5 further include respective central portions 9 having bump openings for contacting respective electrical contacts on a flip-chip which will be located over them. As in conventional substrates, the substrate 1 includes indexing holes 11 to help in positioning the substrate 1 in relation to the integrated circuits and moulding apparatus.

In a first step of the assembly process a flip-chip 13 (shown in FIG. 2, which is a cross section is a plane including two of the holes 7) is attached to each of the regions 9 with its electrical contacts in contact with the bump openings, and a box 15 having an opening is connected to the substrate 1 with the opening facing towards the flip chip 13, so that the box defines a cup enclosing the flip-chip 13. The box 15 may be formed of copper or gold, and may be adhered to the substrate 1. A second integrated circuit 17 is adhered to the opposite face of the substrate 1 (i.e. the one not shown in FIG. 1) and wires 19 are formed between electrical contacts on the second integrated circuit 17 and corresponding electrical contacts on the upper surface of the substrate 1.

The assembly thus formed is shown in cross-section in FIG. 2. As shown in this figure, the substrate 1 includes layers 19 in which electrical connections are provided, sandwiched by insulating layers. The construction of such layers will be familiar to one skilled in flip-chip technology. The contacts of the flip-chip make direct contact to electrical leads in the portion of the layer 19 exposed by the recess 18. Furthermore, as is clear from FIG. 2, the portions 9 of the regions 5 are located within recesses 18 in the lower surface of the substrate 1, so that the surface of the box 15 which is furthermost from the substrate 1 (i.e. lowest in FIG. 2) is still closer to the substrate 1 than the lowest parts of the solder balls 3.

The assembly is then positioned in a conventional moulding device in the orientation shown in FIG. 2. The moulding device applies resin to the upper surface of the substrate to create a resin body 21 including a portion 23 on the upper surface of the substrate 1 having a shape defined by the shape of a mould of the moulding device. During this moulding process, resin flows through the holes 7 into the volume defined by the box 15 and fills that box, so that the resin body 21 further includes a portion 25 on the lower surface of the substrate 1 defined by the internal shape of the box 15. The integrated circuit package thus formed is shown in FIG. 3.

Although not shown in FIG. 3, the box 15 may include openings to ensure that any air which is present in the box 15 before the moulding operation begins is not trapped there in pockets. The openings provide exit paths. Alternatively, the method can be performed at low pressure (e.g. much less than one atmosphere).

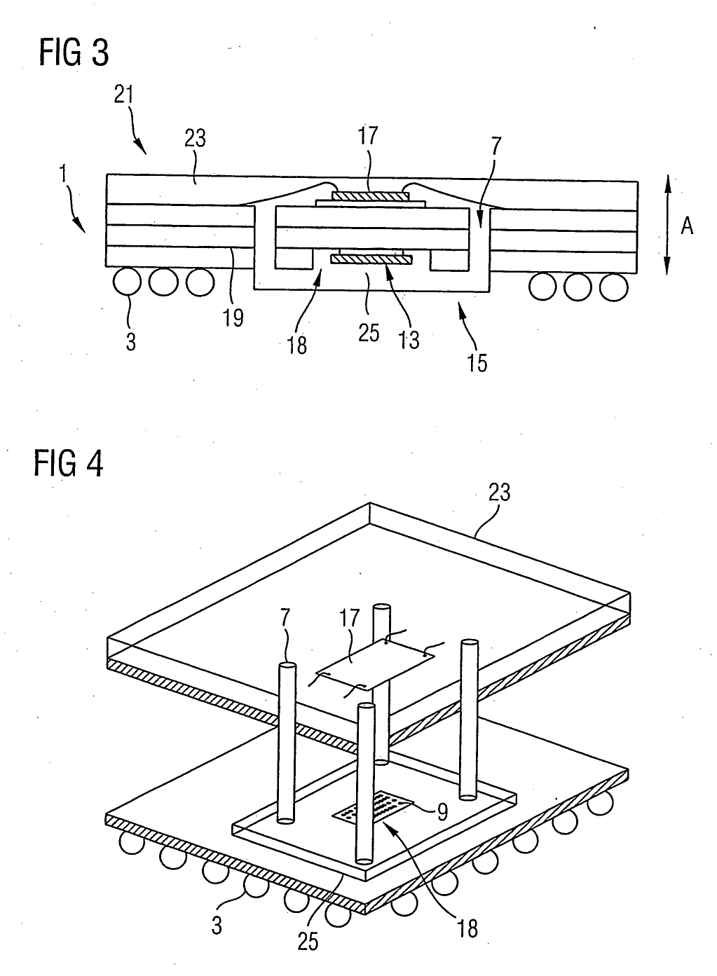

FIG. 4 is a view of the package exploded in the direction marked A in FIG. 3 with the substrate 1 divided into two along one of the planes 19.

Although only a single embodiment of the invention has been shown, many variations are possible within the scope of the invention as will be clear to a skilled reader. For example, the provision of the box 15 is not necessary to the invention, and the shape of the portion 25 of the resin body may instead be defined by a mould which is attached to the lower face of the substrate 1 during the moulding operation and subsequently removed. Furthermore, in alternative embodiments of the invention, the resin may be supplied from under the substrate 1, although this possibility increases the complexity of the operation and is not presently preferred.

1-15. (canceled)

16. A method of packaging integrated circuits comprising:
attaching a first integrated circuit to a first face of a substrate with electrical connection between corresponding contacts of the substrate and the first integrated circuit;
attaching a second integrated circuit to a second face of the substrate with electrical connection between electrical contacts of the substrate and the second integrated circuit; and
encasing the first and second integrated circuits in resin.

17. A method according to claim 16 wherein the substrate includes holes extending between the first face and the second face, the encasing step includes applying the resin to a first side of the substrate and flowing the resin through the holes to the second side of the substrate, whereby the resin forms a single resin body encasing both of the integrated circuits.

18. A method according to claim 17 further comprising, before said encasing step, attaching a box to the second side of the substrate defining a volume for receiving the resin.

19. A method according to claim 18 wherein the box includes openings defining exit paths for gas within the box.

20. A method according to claim 16, wherein the encasing step comprises a molding operation performed at a pressure of less than one atmosphere.

21. A method according to claim 16 wherein the substrate is laminar and at least the first face includes solder balls, the encasing step includes forming the resin on the first face such that the resin on the first face has a maximum distance from a plane of said substrate which is smaller than a maximum extension of the solder balls from the plane of the substrate.

22. A method according to claim 21 wherein the solder balls are arranged in an array having a region without solder balls, and further comprising locating the first integrated circuit in said region.

23. A method according to claim 22, wherein at least one of the first and second integrated circuits comprises a flip chip.

24. A method according to claim 23, wherein the first integrated circuit comprises a flip chip.

25. A method according to claim 24, wherein the flip chip is located in a recessed portion of the substrate.

26. A method according claim 24, wherein the electrical contacts of at least one of the first and second integrated circuits are connected to electric contacts on the substrate by wire bonding.

27. A substrate, comprising:
a plurality of first contacts and a first face configured to attach to a first integrated circuit with electrical connection between the first contacts and the first integrated circuit;
a plurality of second contacts and a second face configured to attach to a second integrated circuit with electrical connection between the second contacts and the second integrated circuit;
wherein the substrate defines a plurality of holes extending between the first face and the second face, the substrate is laminar, and at least the first face includes solder balls.

28. The substrate of claim 27, wherein the solder balls are arranged in an array having a region without solder balls, and wherein said region is configured to receive the first integrated circuit.

29. An integrated circuit package comprising a substrate including electrical contacts and integrated circuits attached to opposite sides of the substrate, the electrical contacts electrically connected to corresponding electrical contacts on the substrate, each of the integrated circuits being encased in resin.

30. An integrated circuit package according to claim 29 wherein a single resin body encases both the integrated circuits and extends through holes in the substrate.

31. An integrated circuit package according to claim 29 wherein the electrical contacts of at least one of the integrated circuits are connected to the electrical contacts on the substrate by wire bonding.

32. An integrated circuit package according to claim 29 further comprising solder balls are arranged on at least a first side of the substrate.

33. An integrated circuit package according to claim 32 wherein the solder balls are arranged in an array having a region without solder balls, and wherein the first integrated circuit is located in said region.

34. An integrated circuit package according to claim 33, wherein at least one of the integrated circuits comprises a flip chip.

35. An integrated circuit package according to claim 34, wherein the flip chip is located in a recessed portion of the substrate.
